(19) United States
(12) Patent Application Publication
(10) Pub. No.: US 2025/0241004 A1
(43) Pub. Date: Jul. 24, 2025

(54) Low-Leakage NEDMOS and LDMOS Devices

(71) Applicant: pSemi Corporation, San Diego, CA (US)

(72) Inventors: Jagar Singh, Clifton Park, NY (US); Akira Fujihara, San Diego, CA (US); Mari Saji, San Diego, CA (US)

(21) Appl. No.: 18/416,779

(22) Filed: Jan. 18, 2024

(51) Int. Cl. H01L 29/78; H01L 29/08; H01L 29/10; H01L 29/66; H01L 29/786

(52) U.S. Cl. CPC H10D 30/65; H10D 30/0221; H10D 30/6706; H10D 62/157; H10D 62/393

(57) ABSTRACT

A number of MOSFET architectures provide high-voltage capability (both drain-source breakdown voltage BV_{DSS} and ON-state breakdown voltage BV_{ON}), low current leakage, and extended linearity. Embodiments of the invention overcome the limitations of conventional NEDMOS and LDMOS device designs by providing a low-resistance path for hole collection and by purposefully exhibiting multiple voltage thresholds V_{TH} in different segments of the device. Embodiments includes NEDMOS and LDMOS device designs having multiple body contact regions for improved hole collection, sub-gate doped stripes or segments for even better hole collection and linearity, and sub-gate doped edge regions for increased local V_{TH} and thus decreased current leakage. P− hole-collection stripes and P+ body contact regions may be formed of a semiconductor material that includes germanium. The inventive MOSFETs may be arranged as multi-MOSFET array elements, and multiple array elements may be arranged in a larger array.

### BACKGROUND

### (1) Technical Field

This invention relates to electronic integrated circuits, and more particularly to electronic integrated circuits having metal-oxide-semiconductor field-effect transistors (MOSFETs).

### (2) Background

Virtually all modern electronic products-including laptop computers, mobile telephones, and electric cars-utilize MOSFET-based integrated circuits (ICs). MOSFET-based ICs may be fabricated on bulk silicon or may be fabricated using a semiconductor-on-insulator (SOI) process, such as silicon-on-insulator, germanium-on-insulator, or silicon/germanium-on-insulator (e.g., a SiGe alloy or a layer of Ge on a layer of Si formed on an insulator).

A number of architectural variations exist for MOSFETs. For example, N-type Extended Drain MOS (NEDMOS) FETs fabricated using SOI processes and Laterally-Diffused MOS (LDMOS) FETs fabricated using bulk silicon are common transistor devices capable of handling relatively high drain voltages. FIG. 1A is a stylized cross-sectional view of a typical prior art SOI IC structure for a single NEDMOS FET 100. The SOI structure includes a substrate 102, an insulating buried-oxide (BOX) layer 104, and an active layer 106 (note that the dimensions for the elements of the SOI IC structure are not to scale; some dimensions have been exaggerated for clarity or emphasis). The substrate 102 is typically a semiconductor material such as silicon. The BOX layer 104 is a dielectric and is often SiO₂ formed as a “top” surface of the silicon substrate 102. In some embodiments, the BOX layer 104 is formed on an optional trap-rich silicon layer (see FIG. 2B) formed on or in the substrate 102. A trap-rich Si layer mitigates parasitic surface conduction and improves device performance at high frequencies.

The active layer 106 may include some combination of implants and/or layers that include dopants, dielectrics, polysilicon, conductors, passivation, and other materials to form active and/or passive electronic components and/or mechanical structures. For example, the NEDMOS FET 100 of FIG. 1A includes an N+ source S, a P-type body region B (also know as a “p-well”), a gate structure G, an N− drift region, and an N+ drain D, all bounded by a shallow trench isolation (STI) structure 107. The extended N− drift region improves device reliability by increasing the ability of the device to withstand higher drain voltages than conventional N-type MOSFETs.

A conductive source contact 112, a conductive gate contact 114, and a conductive drain contact 116, which may be self-aligned silicides (also known as “salicides”), are respectively formed in contact with the source S, the gate structure G, and the drain D. Stylized electrical terminals S, G, and D are shown coupled to the corresponding source contact 112, gate contact 114, and contact 116.

The illustrated gate structure G includes a conductive layer 108, such as N+ doped polysilicon, atop an insulating gate oxide (GOX) layer 110. In the illustrated example, the gate structure G is surrounded by insulating spacers 118. Part of the gate structure G and the N− drift region in the illustrated example are coated with a dielectric 120, such as SiO₂, Si₃N₄, etc., which in turn is overlaid with a salicide block (SAB) layer 122, such as silicon nitride (SiN). In some embodiments, a lightly-doped drain (LDD) region 124 may be formed underneath the spacer 118 adjacent the source S and/or the drain (only the source-side LDD region 124 is shown in FIG. 1A). In some embodiments, a doped halo region 126 may be formed between at least portions of the source S and body B. Similarly, in some embodiments, a doped halo region may be formed between at least portions of the drain D and body B (not shown in FIG. 1A). When the MOSFET 100 is in a conducting (ON) state, a conductive channel is formed within the body B below the gate structure G and between the source S and the drain D.

The BOX layer 104 and the entire active layer 106 (which may include multiple MOSFETs) may be collectively referred to as a “device region” or “substructure” 130 for convenience (noting that other structures or regions may intrude into the substructure 130 in particular IC designs). A superstructure 132 of various elements, regions, and structures may be fabricated on or above the substructure 130 in order to implement particular functionality. The superstructure 132 may include, for example, conductive interconnections from the illustrated MOSFET 100 to other components (including other MOSFETs) and/or external contacts, passivation layers, and protective coatings.

FIG. 1B is a top plan view of the prior art SOI IC structure of FIG. 1A. The cross-section shown in FIG. 1A approximates a view along line X-X of FIG. 1B. The source S, the gate structure G, and the drain D overlay a part 140 of the active layer 106. An N− drift region 141 between the gate structure G and the drain D is shown within a dotted outline.

The illustrated example shows that the source S is associated with multiple source contacts 112 and the drain D is associated with multiple drain contacts 116, while the gate structure G in this particular example is shown as having a single gate contact 114. In conventional N-type MOSFETs, the drift region 141 is omitted and the drain contacts 116 may be positioned closer to the gate structure G. Also shown in FIG. 1B is the top side of a body contact region 142 having an associated conductive body contact 144. In the illustrated example, the body contact region 142 comprises a P+ region formed in electrical contact with the P− body B to provide a fourth terminal to the MOSFET 100.

A bulk semiconductor IC LDMOS structure has an architecture similar to the example NEDMOS of FIG. 1A but omits the BOX layer 104. There are typically other differences, most notably that the N− drift region typically surrounds the N+ drain and generally extends beneath the drain. In addition, any substrate contact may be modified and placed at a different location.

In many applications, such as power amplifiers and low-noise amplifiers (LNAs), high-voltage capability and low current leakage are important design goals for NEDMOS and LDMOS devices. The present invention is directed to MOSFET architectures with high-voltage capability and low current leakage as well as other desirable characteristics compared to conventional MOSFET designs.

### SUMMARY

The present invention encompasses a number of MOSFET architectures that provide high-voltage capability (both drain-source breakdown voltage BV_{DSS} and ON-state breakdown voltage BV_{ON}), low current leakage, and extended linearity. The present invention overcomes the limitations of conventional NEDMOS and LDMOS device designs by manipulating the architecture of a MOSFET so as to provide a low-resistance path for hole collection and to purposefully exhibit multiple voltage thresholds V_{TH} in different segments of the device. Embodiments include NEDMOS and LDMOS device designs having multiple body contact regions for improved hole collection, sub-gate doped stripes or segments for even better hole collection and linearity, and sub-gate doped edge regions for increased local V_{TH} and thus decreased current leakage.

Some MOSFET embodiments include a channel region having one or more hole-collection stripes interdigitated with at least one well region. Some MOSFET embodiments include a channel region having multiple V_{TH} regions and a source region interdigitated by multiple body contact regions. Some MOSFET embodiments include a channel region having one or more P− hole-collection stripes interdigitated with at least one P-well region, and an N+ source region interdigitated by multiple P+ body contact regions. In some embodiments, one or more P− hole-collection stripes and multiple P+ body contact regions are formed of a semiconductor material that includes germanium, such as a heterogeneous or homogenous SiGe alloy. Some embodiments include a gate structure overlying the channel region and having extensions overlapping edge-positioned P− hole-collection stripes. The inventive MOSFETs may be arranged as multi-MOSFET array elements, and multiple array elements may be arranged in an array.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a stylized cross-sectional view of a typical prior art SOI IC structure for a single NEDMOS FET.

FIG. 1B is a top plan view of the prior art SOI IC structure of FIG. 1A.

FIG. 2A is a top plan view of a first embodiment of a NEDMOS IC structure in accordance with the present invention.

FIG. 2B is a stylized cross-sectional view of the NEDMOS IC structure of FIG. 2A taken along line Y-Y.

FIG. 2C is a front perspective view of the NEDMOS IC structure of FIG. 2A.

FIG. 3A is a double graph of (1) transconductance (left vertical axis) versus V_{GS} and (2) I_{DS} (right vertical axis) versus Vas for one modeled example NEDMOS FET in accordance with the present invention.

FIG. 3B is a version of the double graph of FIG. 3A showing transconductance versus V_{GS} for a combination of the graph lines of FIG. 3A.

FIG. 4A is a top plan view of a second embodiment of a NEDMOS IC structure in accordance with the present invention.

FIG. 4B is a top plan view of a third embodiment of a NEDMOS IC structure in accordance with the present invention.

FIG. 5A is a top plan view of a fourth embodiment of a NEDMOS IC structure in accordance with the present invention.

FIG. 5B is a top plan view of a fifth embodiment of a NEDMOS IC structure in accordance with the present invention.

FIG. 6A is an embodiment of a NEDMOS array element that combines four NEDMOS FETs into an area-efficient design.

FIG. 6B is an embodiment of a NEDMOS array that combines four NEDMOS array elements (one instance of which is bounded by dashed lines) like the embodiment shown in FIG. 6A.

FIGS. 7A and 7B are a process flowchart showing the steps of one process suitable for some contemporary IC front-end-of-line (FEOL) foundries.

FIG. 8 is a top plan view of a substrate that may be, for example, a printed circuit board or chip module substrate (e.g., a thin-film tile).

Like reference numbers and designations in the various drawings indicate like elements unless the context requires otherwise.

### DETAILED DESCRIPTION

The present invention encompasses a number of MOSFET architectures that provide high-voltage capability (both drain-source breakdown voltage BV_{DSS} and ON-state breakdown voltage BV_{ON}), low current leakage, and extended linearity. The present invention overcomes the limitations of conventional NEDMOS and LDMOS device designs by manipulating the architecture of a MOSFET so as to provide a low-resistance path for hole collection and to purposefully exhibit multiple voltage thresholds V_{TH} in different segments of the device. Embodiments includes NEDMOS and LDMOS device designs having multiple body contact regions for improved hole collection, sub-gate doped stripes or segments for even better hole collection and linearity, and sub-gate doped edge regions for increased local V_{TH} and thus decreased current leakage. A number of these concepts may also be applied to NMOS devices, as most of the novel changes are only on the source side of a device.

To improve NEDMOS and LDMOS device performance, it is important to minimize the leakage current (stacks of NEDMOS devices in particular are very sensitive to leakage current). Conventional NEDMOS and LDMOS devices generally minimize leakage current I_{DOFF}, by increasing the channel length LG, but doing so hurts radio frequency (RF) performance in particular.

Reducing leakage current also enables a higher device breakdown voltage, BV_{DSS}. Higher device operating temperature also leads to higher leakage current. For example, LDMOS power amplifiers are quite susceptible to leakage currents since LDMOS devices draw a significant amount of current resulting in self-heating. Accordingly, reducing internal resistance within such devices reduces self-heating, and generally reduces leakage currents in addition to increasing hole collection efficiency and enhancing transconductance (Gm) values.

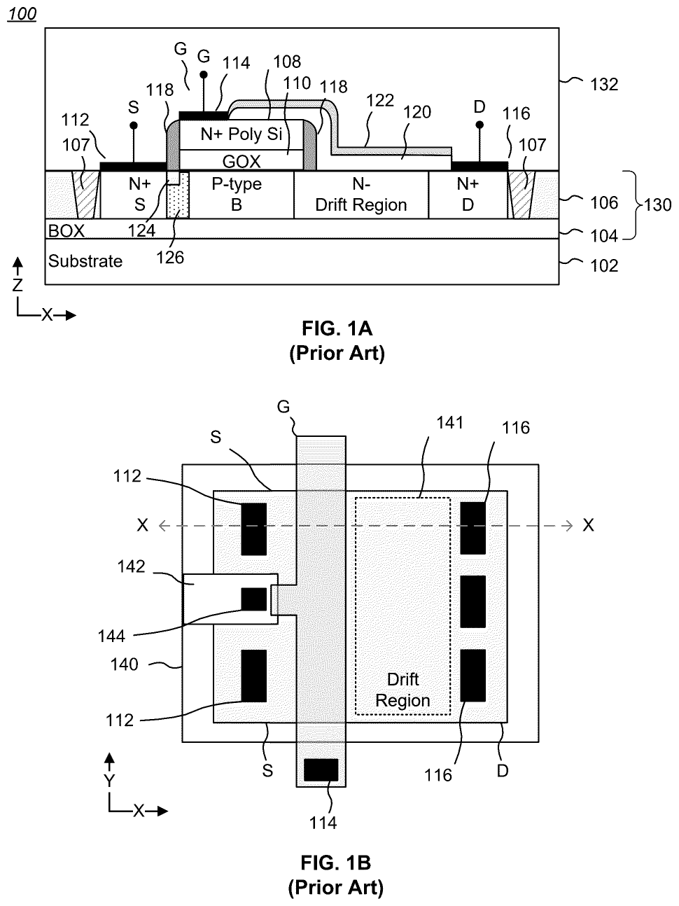

Referring back to FIG. 1B, the MOSFET body contact 144—and thus the body contact region 142—is commonly coupled to a bias node such as a power supply, to circuit ground, or to the source S (although other connections are possible). Holes from hot-carriers (generated, for example, from the phenomena of impact ionization) within the body B flow through the body contact region 142 to the body contact 144. Hot-carrier injection is a phenomenon in solid-state electronic devices where a charge carrier (electron or hole) gains sufficient kinetic energy to overcome a potential barrier necessary to break an interface state. In the case of N-type MOSFETs, electrons are trapped within the gate oxide layer 110, while holes move toward the body or substrate contacts. Accumulation of holes in the body of the MOSFET raises the body potential and increases the drive current, a phenomenon sometimes known as a floating body effect or a “kink” effect. A body contact region 142 can reduce the problems associated with hot carriers by collection of holes.

One aspect of the present invention is the use of multiple body contact regions to improve hole collection. Another aspect of the present invention is the use of sub-gate doped stripes or segments for even better hole collection and linearity. The sub-gate doped stripes or segments may include germanium (e.g., as a pure element, or as a heterogeneous or homogenous SiGe alloy, including Ge-doped Si as well as graded Ge and Si mixtures). Still another aspect of the present invention is the use of sub-gate doped edge regions for increased local V_{TH} and thus decreased current leakage.

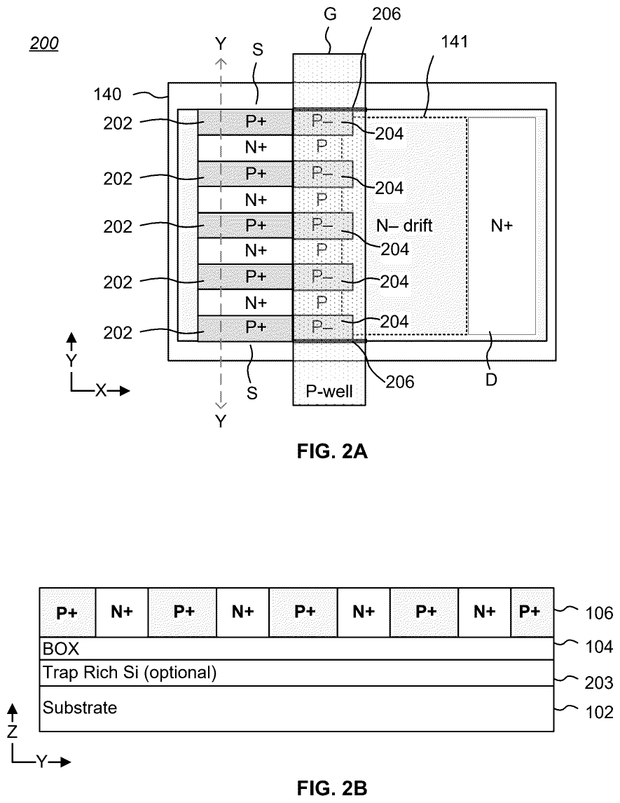

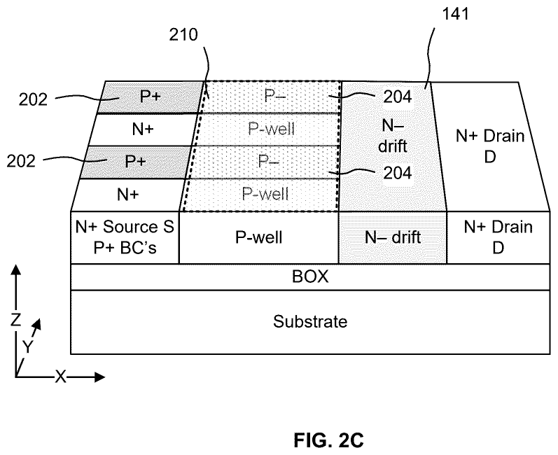

For example, FIG. 2A is a top plan view of a first embodiment of a NEDMOS 200 IC structure in accordance with the present invention. FIG. 2B is a stylized cross-sectional view of the NEDMOS 200 IC structure of FIG. 2A taken along line Y-Y. FIG. 2C is a front perspective view of the NEDMOS 200 IC structure of FIG. 2A.

The NEDMOS 200 IC structures in FIGS. 2A-2C is similar to the NEDMOS structure of FIG. 1B in a number of aspects, but differ in that the source S region includes multiple P+ body contact regions 202 formed as segments or stripes along the X-dimension and across the Y-dimension of the source S region. Holes that might be generated underneath and near the drain-side edge of the gate structure G are preferentially attracted to the multiple P+ body contact regions 202, thus reducing HCI effects and increasing BV_{DSS} and BV_{ON}. For example, in comparative simulations, a conventional single P+ body contact region NEDMOS exhibited a BV_{DSS} of about 10.3V, while an otherwise similar NEDMOS having multiple P+ body contact regions 202 exhibited a BV_{DSS} of about 11.8V, an approximately 15% improvement.

In addition, compared to a conventional device having a single body contact region, the multiple P+ body contact regions 202 shorten the average path length that holes must travel before collection, thus reducing the internal resistance of the device.

FIG. 2B shows the alternating N+ and P+ regions on the source-side of the gate structure G. Also shown in FIG. 2B is an optional trap rich silicon (Si) layer 203 between the BOX layer 104 and the substrate 102, typical of a NEDMOS FET in RF circuitry. In an LDMOS device, the trap rich Si layer 203 and the BOX layer 104 would be absent. Instead, an LDMOS device may include an N-type multiple-layer triple-well implant layer on which the active layer 106 and remaining structures of the LDMOS device are formed. In such a structure, the P-well of the transistor overlays the deeper N-type triple-well implant layer. With suitable biasing, the triple-well implant layer provides DC isolation similar to the isolation provided by the BOX layer 106 in an NEDMOS device.

While the example device structures in FIGS. 2A and 2B show five P+ body contact regions 202, the number may vary to be two or more as a matter of design choice and fabrication process-dependent feature size limitations.

FIG. 2A also includes one or more P− hole-collection stripes 204 formed as X-dimension stripes across the Y-dimension of the gate structure G and underneath the gate structure G. The P− hole-collection stripes 204 are in contact with corresponding P+ body contact regions 202 and are doped to have a lower resistance to the flow of holes than the p-well (body region B). P+ represents higher levels of doping than P−, and P− represents higher levels of doping than the p-well. Accordingly, holes generated near the drain-side edge of the gate structure G are preferentially attracted to the P− hole-collection stripes 204. The closer positioning of P− material near the drain-side edge of the gate structure G allows for faster and more efficient hole collection and conveyance of such holes to the P+ body contact regions 202 than if the holes had to drift all of the way to the source-side edge of the gate structure G.

In FIG. 2A, the P− hole-collection stripes 204 extend almost to the drain-side edge of the gate structure G, which provides a lower resistance to hole collection. In alternative embodiments, the drain-side edges of the P− hole-collection stripes 204 are spaced away from the N− drift region, which increases the breakdown voltage BV_{DSS}.

In preferred embodiments, two of the P− hole-collection stripes 204 are respectively positioned at the Y-dimension lateral edges 206 of the device channel beneath the gate structure G such that higher local V_{TH} regions are formed adjacent to the lateral edges 206. Higher local V_{TH} at the lateral edges 206 reduces current leakage due to the well-known parasitic “edge transistor” effect in N-type FETs. In some embodiments, the two edge P− hole-collection stripes 204 may be wider (larger Y dimension) than the inner P− hole-collection stripes 204. Wider edge P− hole-collection stripes 204 further increases the local V_{TH}, thus further reducing leakage current at the edges of the device.

FIG. 2C shows the alternating N+ source stripes S and P+ body contact (BC) regions 202 on the source-side of the gate structure G as well as the alternating P− hole-collection stripes 204 and P-well stripes beneath the gate structure G (only the footprint 210—in dotted outline—of the gate structure G is shown).

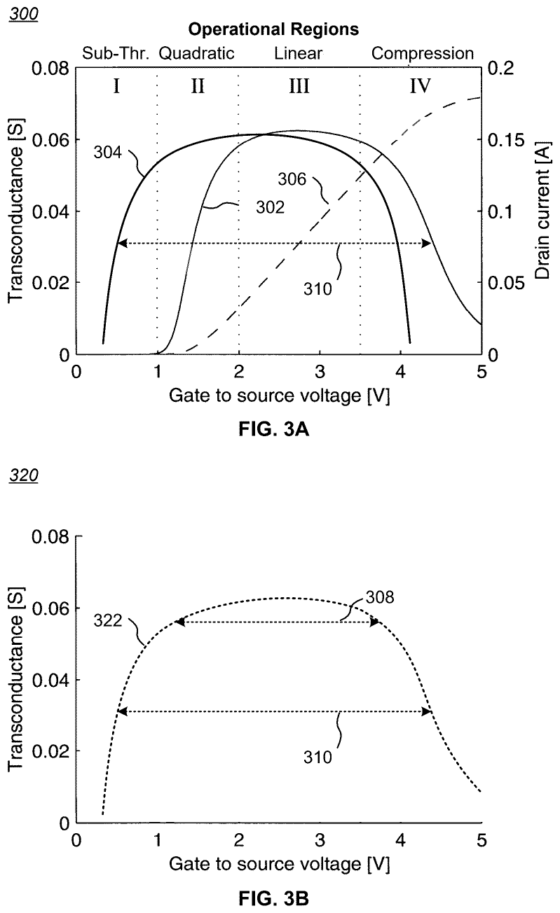

The interior (non-edge) P− hole-collection stripes 204 also result in a higher local V_{TH}. The result of interdigitating P− hole-collection stripes 204 with P-well stripes in the channel beneath the gate structure G is to functional create two intermeshed transistors, one with a lower V_{TH} (through the P-well stripes) and one with a higher V_{TH} (through the P− hole-collection stripes 204). A multiple V_{TH} MOSFET exhibits multiple transconductance versus gate-to-source voltage (V_{GS}) curves and multiple I_{DS} versus V_{GS} curves. For example, FIG. 3A is a double graph 300 of (1) transconductance (left vertical axis) versus V_{GS} and (2) I_{DS} (right vertical axis) versus V_{GS} for one modeled example NEDMOS FET in accordance with the present invention. Graph line 302 corresponds to one or more segments of the MOSFET having a higher V_{TH}. Graph line 304 corresponds to one or more segments of the MOSFET having a lower V_{TH}. Dashed graph line 306 corresponds to the combined I_{DS} of the MOSFET segments, thereby extending the linear device operation behavior.

The labels at the top of the graph 300 (“sub-threshold”, “quadratic”, “linear”, “compression”) correspond to conventional operational regions for the aspect of the MOSFET represented by graph line 302. In operational region I, the sub-threshold region, I_{DS} is usually taken to depend exponentially on V_{GS}. In operational region II, as V_{GS} increases, I_{DS} starts to rise quadratically, which implies that the transconductance (gₘ) should rise linearly. In operational region III, higher values of Vas result in a linear dependence on V_{GS}, with a resulting approximately constant transconductance; MOSFET devices are usually designed to present approximately constant transconductance over a region as wide as possible to achieve better intermodulation distortion (IMD) performance. In operational region IV, for even higher values of V_{GS}, the transconductance will drop and the current compresses.

The lower V_{TH} graph line 304, while otherwise resembling graph line 302, is essentially shifted to the left, indicating that the low V_{TH} segments of the MOSFET traverse the conventional operational regions at lower Vas values than the high V_{TH} segments of the MOSFET. Thus, for example, the linear range of graph line 304 (lower V_{TH} segments) partly occurs within the quadratic range of graph line 302 (higher V_{TH} segments).

FIG. 3B is a version of the double graph of FIG. 3A showing transconductance versus Vas for a combination of the graph lines 302, 304 of FIG. 3A. The combination is shown as dotted graph line 322 in FIG. 3B, and indicates a wider range of Vas voltages in which the different V_{TH} segments of the MOSFET are within respective linear ranges, indicated by dotted line 308. Thus, the multiple V_{TH} regions provide extended linearity compared to a MOSFET having a single V_{TH} region. More generally, the combination of the graph lines 302, 304 provides a wider range of V_{GS} voltages in which the different V_{TH} segments operate within a usable transconductance range-0.03 in this example, indicated by dotted line 310.

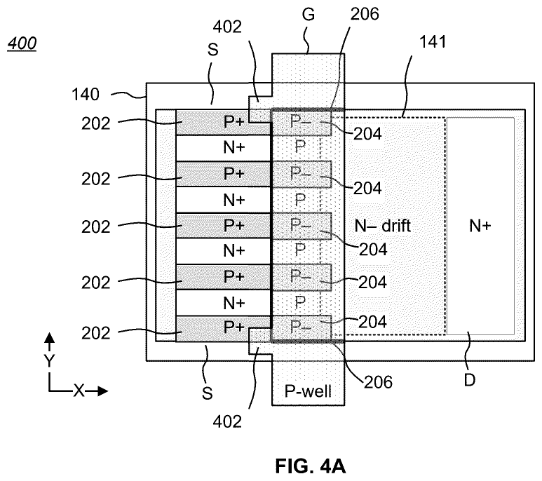

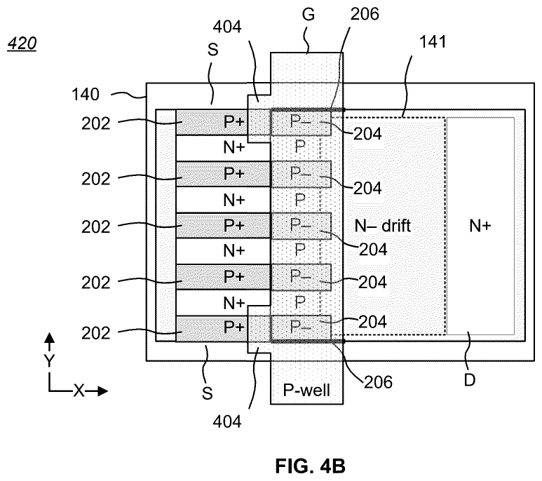

Embodiments of the present invention may include modified gate structures G that further reduce leakage current. For example, FIG. 4A is a top plan view of a second embodiment of a NEDMOS 400 IC structure in accordance with the present invention. Similar in most aspects to the NEDMOS 200 IC of FIG. 2A, the gate structure G is modified to include extensions 402 over the edge P+ body contact regions 202, which further increase the V_{TH} of the parasitic transistor at the lateral edges 206.

FIG. 4B is a top plan view of a third embodiment of a NEDMOS 420 IC structure in accordance with the present invention. Similar in most aspects to the NEDMOS 400 IC of FIG. 4A, the gate structure G is modified to include even wider (in the Y dimension) extensions 404 over the edge P+ body contact regions 202 as well as over a portion of the adjacent N+ source regions. Allowing wide extensions 404 improves manufacturability without significantly affecting performance.

The example embodiments described above utilize suitably doped silicon for the N+ source S and drain D, the multiple P+ body contact regions 202, and the one or more P− hole-collection stripes 204. However, one or more of such structures may be composed of or include other semiconductor materials. For example, the multiple P+ body contact regions 202 and the one or more P− hole-collection stripes 204 may include germanium (e.g., as a pure element, or as a heterogeneous or homogenous SiGe alloy, including Ge-doped Si as well as graded Ge and Si mixtures). Hole mobility in Ge and SiGe generally is greater than hole mobility in Si alone, particularly when strained. For example, in an active layer 106 of Si having a <110> orientation, Ge has about 4 to 5 times greater hole mobility than Si when compressed between 2 and 3 gigapascals (GPa), with various SiGe alloys having intermediate hole mobilities.

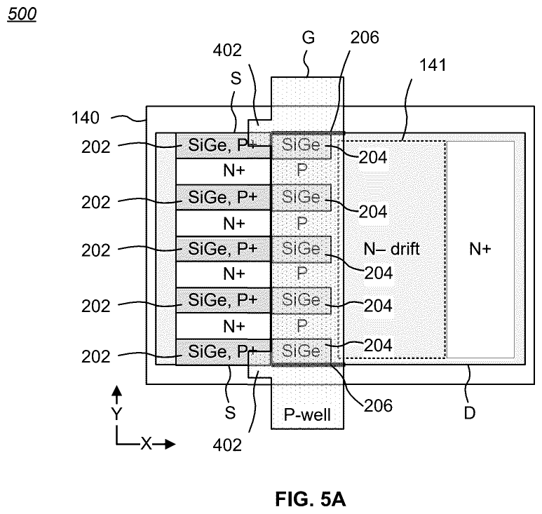

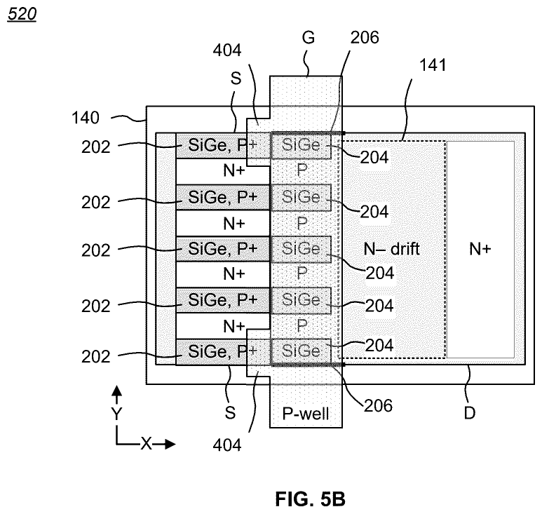

FIG. 5A is a top plan view of a fourth embodiment of a NEDMOS 500 IC structure in accordance with the present invention. The NEDMOS 500 IC structure is similar in most aspects to the NEDMOS 400 IC of FIG. 4A, with a gate structure G modified to include extensions 402 over the edge P+ body contact regions 202. However, the P+ body contact regions 202 may comprise P+ doped Si or P+Ge or a P+ SiGe alloy. Further, the P− hole-collection stripes 204 beneath the gate structure G may comprise P− doped Si or Ge or a SiGe alloy; in the latter cases, the Ge or SiGe may not be intentionally doped (because of Ge's greater hole mobility characteristic) or may be P− doped.

FIG. 5B is a top plan view of a fifth embodiment of a NEDMOS 520 IC structure in accordance with the present invention. The NEDMOS 520 IC structure is similar in most aspects to the NEDMOS 500 IC of FIG. 5A, except that the gate structure G is modified to include even wider (in the Y dimension) extensions 404 over the edge P+ body contact regions 202 as well as over a portion of the adjacent N+ source regions.

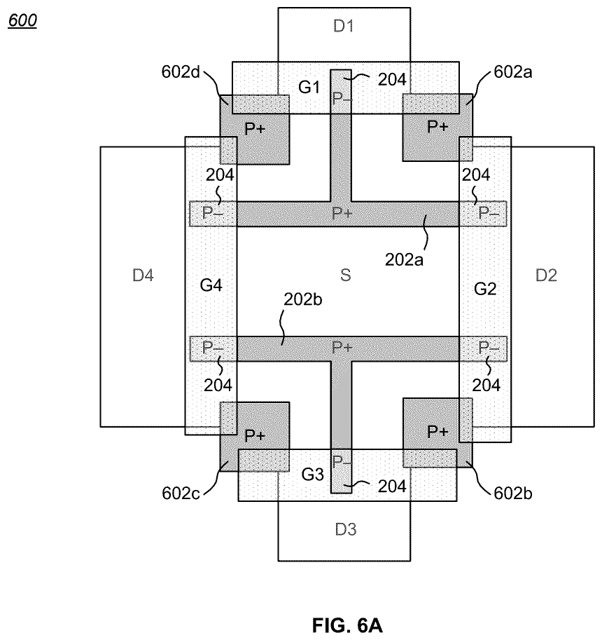

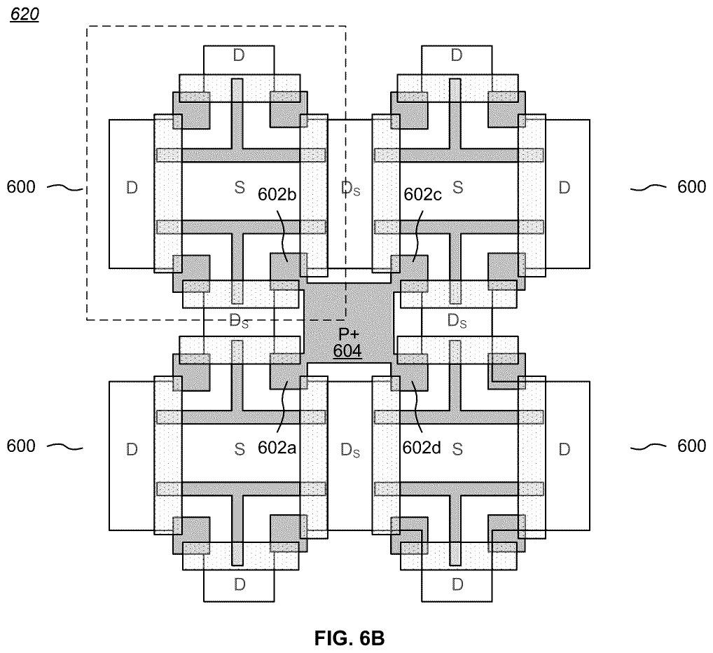

Another aspect of the present invention includes clustering multiple NEDMOS FET structures into an area-efficient NEDMOS array element having reduced parasitic gate-to-source capacitance, C_{GS}. A NEDMOS array element may be used individually or multiple NEDMOS array elements may be combined in a larger array. For example, FIG. 6A is an embodiment of a NEDMOS array element 600 that combines four NEDMOS FETs into an area-efficient design. In the illustrated example, a common source region S is coupled to four drain regions D1-D4 through channels defined by respective gate structures G1-G4. Multiple P+ body contact regions 202a, 202b provide hole collection, generally for more than one FET (source S/drain Dn pairing). For example, P+ body contact region 202a provides hole collection on the source side of the FETs having drains D1, D2, and D4. Similarly, P+ body contact region 202b provides hole collection on the source side of the FETs having drains D2, D3, and D4.

Underneath each gate structure G1-G4 are one or more P− hole-collection stripes 204 to enhance collection of holes and convey the holes to corresponding portions of the P+ body contact regions 202a, 202b.

A NEDMOS array element may combine a different number of NEDMOS FETs. For example, a NEDMOS array element may combine two or three NEDMOS FETs that share a common source region S, which results in an area-efficient structure.

The area-efficient layout of the four NEDMOS FETs in FIG. 6A can benefit from a further reduction in parasitic Cos by adding P+ corner “cap” body contact regions 602a-602d to partially cover the source-side edges of the gate structures G1-G4 and corresponding portions of the underlying channel regions.

Multiple NEDMOS array elements may be “tiled” together for even greater IC area efficiency. For example, FIG. 6B is an embodiment of a NEDMOS array 620 that combines four NEDMOS array elements 600 (one instance of which is bounded by dashed lines) like the embodiment shown in FIG. 6A. (Some reference characters for the NEDMOS array elements 600 have been omitted to reduce clutter; see FIG. 6A for a full set of reference characters). Horizontally and vertically adjacent NEDMOS array elements 600 share common drain regions D_{S}. In addition, the NEDMOS array 620 may include a central P+ body contact region 604 coupling an inner set of P+ corner “cap” body contact regions 602a-602d associated with the combines four NEDMOS array elements 600.

NEDMOS array elements 600 can be standalone structures or combined in a variety of array sizes. Most generally, a NEDMOS array may comprise M×N NEDMOS array elements 600, where M and N are both integers greater than or equal to one and where M and N may be equal to or different from each other. NEDMOS arrays are particularly well-suited for use in power amplifiers (PAS) and LNAs.

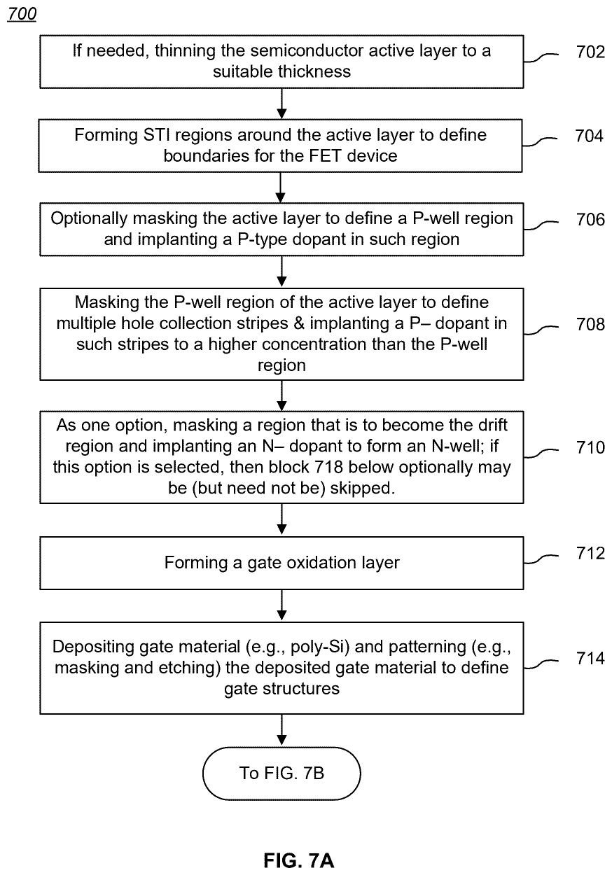

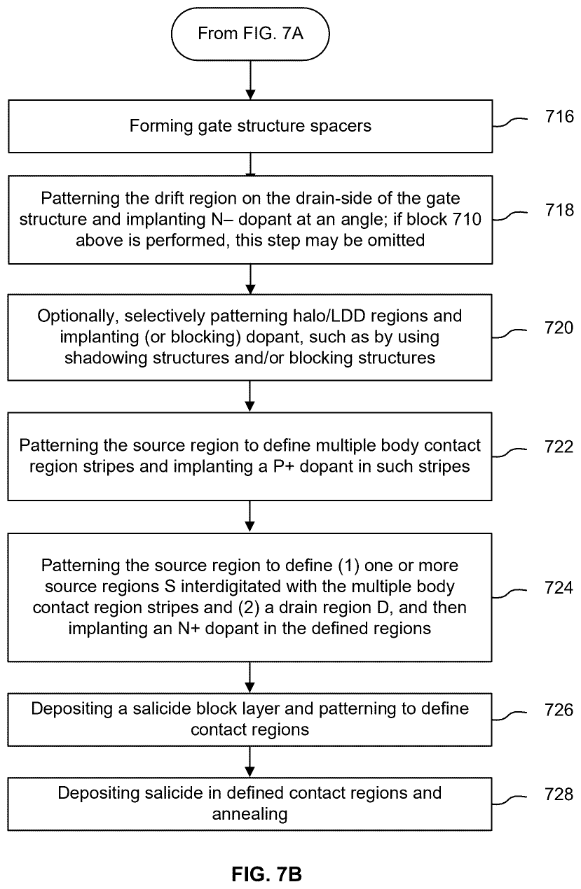

NEDMOS FETs in accordance with the present invention may be fabricated using additive processes, subtractive processes, or a combination of additive and subtractive processes. FIGS. 7A and 7B are a process flowchart 700 showing the steps of one process suitable for some contemporary IC front-end-of-line (FEOL) foundries. Note that some conventional steps, such as planarization, passivation, details of masking and etching, and superstructure formation have been omitted as known to those of ordinary skill in the art. The example process for a NEDMOS FET includes:
(1) If needed, thinning the semiconductor active layer 106 (e.g., Si, Ge, SiGe alloy) to a suitable thickness [Block 702]. For example, commercially available SOI wafers may have an active layer thickness of about 750 Å; it may be useful for some applications, particularly for RF ICs, to thin the active layer, such as to about 500 Å-550 Å.
(2) Forming shallow trench isolation (STI) regions around the active layer to define boundaries for the MOSFET device [Block 704].
(3) Optionally masking the active layer 106 to define a P-well region and implanting a P-type dopant (e.g., boron or boron difluoride) in such region [Block 706].
(4) Masking the P-well region of the active layer 106 to define one or more hole-collection stripes 204 and implanting a P− dopant in such stripes to a higher concentration than the P-well region [Block 708].
(5) As one option, masking a region that is to become the drift region and implanting an N− dopant to form an N-well. This option is often an easy manufacturing solution since many processes already utilize an existing N-well mask which can be slightly modified to implement this option. If this option is selected, then step (9) below optionally may be (but need not be) skipped. Note that the N-well should be placed so that it will partially underlie the later-formed gate structure. [Block 710].
(6) Forming a gate oxidation layer [Block 712].
(7) Depositing gate material (e.g., poly-Si) and patterning (e.g., masking and etching) the deposited gate material to define gate structures [Block 714].
(8) Forming gate structure spacers, thus completing the gate structure (oxide, gate material, spacers) [Block 716].
(9) Patterning the drift region on the drain-side of the gate structure and implanting N− dopant at an angle [Block 718]. If step (5) above is performed, this step may be omitted, but need not be; in the latter case, extra N− doping occurs within the drift region.
(10) Optionally, selectively patterning halo/LDD regions and implanting (or blocking) dopant, such as by using shadowing structures and/or blocking structures [Block 720].
(11) Patterning the source region to define multiple body contact region stripes 202 and implanting a P+ dopant in such stripes [Block 722].
(12) Patterning the source region to define (1) one or more source regions S interdigitated with the multiple body contact region stripes 202 and (2) a drain region D, and then implanting an N+ dopant in the defined regions [Block 724].
(13) Depositing a salicide block layer and patterning to define contact regions [Block 726].
(14) Depositing salicide (e.g., NiSi) in defined contact regions and annealing [Block 728].

Other fabrication recipes may be used to fabricate NEDMOS FETs having multiple P+ body contact regions 202 and one or more P− hole-collection stripes 204. While the above description has focused on the structure and methods of manufacture of NEDMOS FETs, the structure and fabrication of similar LDMOS FETs would be essentially the same, albeit starting with a different substrate. Further, the structures and methods taught by this disclosure may be readily adapted to apply to P-type MOSFETs, with material polarities reversed, and consequently may also be used with complementary metal-oxide-semiconductor (CMOS) circuitry.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

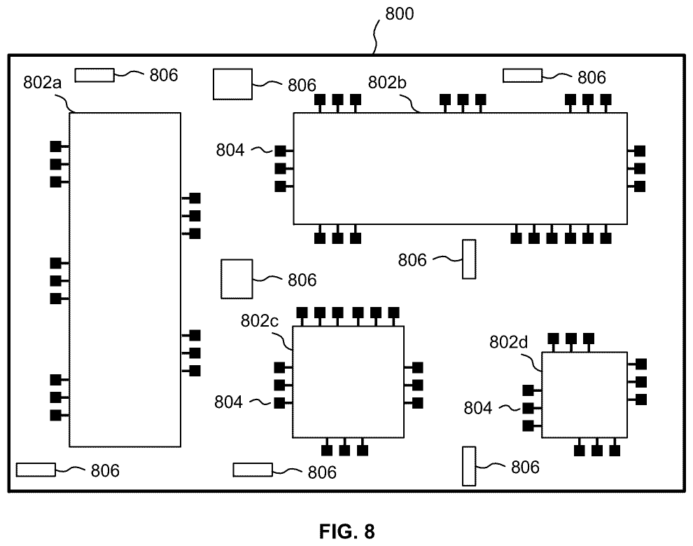

As one example of further integration of embodiments of the present invention with other components, FIG. 8 is a top plan view of a substrate 800 that may be, for example, a printed circuit board or chip module substrate (e.g., a thin-film tile). In the illustrated example, the substrate 800 includes multiple ICs 802a-802d having terminal pads 804 which would be interconnected by conductive vias and/or traces on and/or within the substrate 800 or on the opposite (back) surface of the substrate 800 (to avoid clutter, the surface conductive traces are not shown and not all terminal pads are labelled). The ICs 802a-802d may embody, for example, signal switches, active and/or passive filters, amplifiers (including one or more LNAs), and other circuitry. For example, IC 802b may incorporate one or more instances of a NEDMOS FET in accordance with the present invention.

The substrate 800 may also include one or more passive devices 806 embedded in, formed on, and/or affixed to the substrate 800. While shown as generic rectangles, the passive devices 806 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 800 to other passive devices 806 and/or the individual ICs 802a-802d. The front or back surface of the substrate 800 may be used as a location for the formation of other structures.

Another aspect of the invention includes methods for fabricating a MOSFET. One method includes: providing a substrate; forming an insulator layer on the substrate; forming an active layer on the insulator layer; forming a well region in the active layer; and forming at least one hole-collection stripe interdigitated with the well region. In some embodiments, the at least one hole-collection stripe has a higher voltage threshold V_{TH} than the well region. In some embodiments, the method further includes forming a source region interdigitated by multiple body contact regions.

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as BiCMOS, LDMOS, BCD, GaN HEMT, GaAs pHEMT, MESFET, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to MOSFET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly MOSFETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A metal-oxide-semiconductor field-effect transistor (MOSFET) including a channel region having one or more hole-collection stripes interdigitated with at least one well region.

2. The MOSFET of claim 1, wherein the one or more hole-collection stripes are P− hole-collection stripes.

3. The MOSFET of claim 2, wherein a first P− hole-collection stripe is positioned at a first lateral edge of the channel region and a second P− hole-collection stripe is positioned at a second lateral edge of the channel region.

4. The MOSFET of claim 1, wherein the one or more hole-collection stripes have a higher voltage threshold V_{TH} than the at least one well region.

5. The MOSFET of claim 4, wherein a first hole-collection stripe is positioned at a first lateral edge of the channel region and a second hole-collection stripe is positioned at a second lateral edge of the channel region.

6. A metal-oxide-semiconductor field-effect transistor (MOSFET) including a channel region having multiple V_{TH} regions and a source region interdigitated by multiple body contact regions.

7. The MOSFET of claim 6, wherein the multiple body contact regions are P+ body contact regions and the source region is an N+ source region.

8. A metal-oxide-semiconductor field-effect transistor (MOSFET) including:
(a) a channel region having one or more P− hole-collection stripes interdigitated with at least one P-well region; and
(b) an N+ source region interdigitated by one or more P+ body contact regions.

9. The MOSFET of claim 8, wherein the one or more P− hole-collection stripes are aligned with and in electrical contact with the multiple P+ body contact regions.

10. The MOSFET of claim 8, further including:
(a) a drain region; and
(b) a drift region between the channel region and the drain region.

11. The MOSFET of claim 10, wherein the drift region is an N− drift region and the drain region is an N+ drain region.

12. The MOSFET of claim 8, wherein the one or more P− hole-collection stripes and the one or more P+ body contact regions are formed of a semiconductor material that includes germanium.

13. The MOSFET of claim 8, wherein a first P− hole-collection stripe is positioned at a first lateral edge of the channel region and a second P− hole-collection stripe is positioned at a second lateral edge of the channel region.

14. The MOSFET of claim 13, further including a gate structure overlying the channel region and having a first extension overlapping a first P+ body contact region abutting the first P− hole-collection stripe and a second extension overlapping a second P+ body contact region abutting the second P− hole-collection stripe.

15. The MOSFET of claim 13, further including a gate structure overlying the channel region and having a first extension overlapping a first P+ body contact region abutting the first P− hole-collection stripe and a first portion of the N+ source region adjacent to the first P− hole-collection stripe, and a second extension overlapping a second P+ body contact region abutting the second P− hole-collection stripe and a second portion of the N+ source region adjacent to the second P− hole-collection stripe.

16.-20. (canceled)
